(19) United States
(12) Patent Application Publication
(10) Pub. No.: US 2007/0155105 A1
(43) Pub. Date: Jul. 5, 2007

(54) Method for forming transistor of semiconductor device

(75) Inventors: Hye Jin Seo, Suwon-si (KR); An Bae Lee, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Gyunggi-do (KR)

(21) Appl. No.: 11/485,748

(22) Filed: Jul. 12, 2006

(30) Foreign Application Priority Data
Dec. 29, 2005 (KR) 2005-134280

(51) Int. Cl. H01L 21/336

(52) U.S. Cl. 438/283

(57) ABSTRACT

A method for forming transistors of a semiconductor device includes forming a plurality of gate stacks on a semiconductor substrate; and forming a spacer oxide film on the semiconductor substrate having the plurality of gate stacks formed thereon using a single-type radical-assisted CVD apparatus. The method further includes oxidizing the surfaces of the plurality of gate stacks, after the formation of the gate stacks; forming LDD regions in the semiconductor substrate at both sides of the plurality of gate stacks; and sequentially forming a buffer oxide film and a spacer nitride film on the plurality of gate stacks.

### BACKGROUND OF THE INVENTION

The present invention relates to a method for forming transistors of a semiconductor device, and more particularly to a method for fabricating a semiconductor device in which a spacer oxide film having a uniform thickness is formed on a single substrate. The deposition is done using a radical-assisted CVD apparatus for generating plasma with gas supplied from the outside of a reaction chamber.

A transistor of a semiconductor device, particularly a peri-transistor comprising of a PMOS and a NMOS, has electrical characteristics which depends highly on the thickness uniformity of the gates. That is, gates having a uniform thickness, which are formed in a single wafer or different wafers, uniformly improve electrical characteristics throughout the semiconductor device, thereby allowing the semiconductor device to be operated more stably and improve the yield of the device.

Hereinafter, a conventional process for forming transistors of a semiconductor device having the above gates will be described.

First, a plurality of gate stacks, each comprising a gate insulating film, a gate conductive film, and a hard mask film, are formed on a semiconductor substrate. A low-concentration impurity is injected into the semiconductor substrate, thereby forming LDD regions on the semiconductor substrates at both sides of the plurality of gate stacks.

Thereafter, a spacer oxide film (such as a TEOS film) is deposited on the plurality of gate stacks using CVD (such as LPCVD). Blanket etching is performed on the spacer oxide film, thereby forming gate spacers at both side walls of the gate stacks. Thus, a plurality of gates having the gate stacks and the gate spacers are formed on the semiconductor substrate.

Then, a high-concentration impurity is injected into the semiconductor substrate at both sides of the gates, thereby forming sources/drains. Consequently, a transistor of a semiconductor device having an LDD structure is obtained.

The above conventional method has been applied to a manufacturing method of a peri-transistor having a PMOS and a NMOS requiring high-speed operation, and applied to other manufacturing processes of various semiconductor devices.

As semiconductor devices are being recently developed towards higher-integration and hyperfine trends, the density of gate stacks formed on semiconductor substrates having the same dimensions is increased. Further, since regions in which a large number of the gate stacks are densely arranged and regions in which a small number of gate stacks are sparsely arranged are simultaneously present on a single semiconductor substrate, the densities of the gate stacks in the two regions are different.

Accordingly, regardless of the densities of the gate stacks, gate spacers having a uniform thickness are formed on side walls of the gate stacks in all regions, and a plurality of gates comprising the gate stacks and the gate spacers are formed on the semiconductor substrate to a uniform thickness. Thereby, the transistors of a semiconductor device comprising the gates has uniformly improved electrical characteristics.

However, when a spacer oxide film is formed by CVD (such as LPCVD) and gate spacers are formed by blanket-etching the spacer oxide film, the spacer oxide film formed by CVD cannot have a uniform thickness on a semiconductor substrate on which a plurality of gate stacks are arranged at different densities according to it's region. Thus the gate spacers formed on the side walls of the gate stacks in all regions cannot have a uniform thickness. That is, when the spacer oxide film is formed by CVD, the spacer oxide film in regions where a large number of the gate stacks are densely arranged has a small thickness and the spacer oxide film in regions where a small number of the gate stacks are sparsely arranged has a large thickness. Thereby, the gate spacers obtained by blanket-etching the spacer oxide film on a single semiconductor substrate have different thicknesses according to regions within the substrate. The gate spacers formed on different semiconductor substrates have different thicknesses as well.

Since the thickness of the gate spacers vary, the thickness of the gates having the gate stacks and the gate spacers also vary. Thus, electrical characteristics of a transistor of a semiconductor device, for example Vt of a PMOS, may not be uniform. That is, the Vt difference among regions of the PMOS is increased.

Accordingly, in the above conventional method, electrical characteristics of the transistor of the semiconductor device (such as Vt characteristics of a PMOS) are not uniform and the yield of the semiconductor device is drastically lowered. Further, the transistor of the semiconductor device, particularly a peri-transistor, may malfunction and not operate stably.

In order to solve the above problems, instead of CVD (such as LPCVD) the spacer oxide film is formed using ALD so as to form gate spacers and gates having a uniform thickness.

However, as apparent to those skilled in the art, ALD has a low deposition speed so that only a single atomic layer is grown per cycle of ALD which prevents mass production. Thus, ALD cannot be substantially applied to the mass production process of the semiconductor devices.

Accordingly, the development of a high speed process for forming a spacer oxide film having a uniform thickness regardless of the density of a plurality of gate stacks would be desirable.

### SUMMARY OF THE INVENTION

One embodiment relates to a method for forming transistors of a semiconductor device in which a spacer oxide film having a uniform thickness is formed using a radical-assisted CVD apparatus for generating plasma using gas supplied from the outside of a reaction chamber.

A method for forming transistors of a semiconductor device comprises forming a plurality of gate stacks on a semiconductor substrate; and forming a spacer oxide film on the semiconductor substrate having the plurality of gate stacks formed thereon using a single-type radical-assisted CVD apparatus.

The method further comprises of oxidizing the surfaces of the plurality of gate stacks after the formation of the gate stacks; forming LDD regions in the semiconductor substrate at both sides of the plurality of gate stacks; and sequentially forming a buffer oxide film and a spacer nitride film on the plurality of gate stacks.

In one embodiment, a method for forming a semiconductor device having a plurality of transistors includes forming a first gate stack on a first region of a substrate. The first region has a high density of gate stacks. The first gate stack is associated with a first transistor. A second gate stack is formed on a second region of a substrate. The second region has a low density of gate stacks. The second gate stack is associated with a second transistor. First and second gate oxide spacers are formed at least on sidewalls of the first and second gate stacks, respectively. The gate oxide spacer forming step includes: flowing a first gas into a plasma generating chamber of a deposition apparatus to generate a plasma and a plurality of radicals using the first gas; flowing the radicals into a film growing chamber that is separated from the plasma generating chamber, so that the radicals may react with a second gas provided in the film growing chamber to form a spacer oxide film on the first and second gate stacks; and etching the spacer oxide film to define the first and second gate oxide spacers for the first and second gate stacks, respectively.

The reaction of the radicals of the first gas with the second gas provides the spacer film with substantially the same thickness in the first and second regions, so that the first and second transistors associated with the first and second gate spacers have a reduced threshold voltage variance.

The difference between a first threshold voltage of the first transistor and a second threshold voltage of the second transistor is no more than 165 mV in absolute term, wherein the 165 mV is the maximum threshold voltage variance for the transistors formed on the substrate. The substrate is a wafer.

### BRIEF DESCRIPTION OF THE DRAWINGS

FIGS. 1 to 4 are sectional views for illustrating a method for forming transistors of a semiconductor device in accordance with an embodiment of the present invention;

FIGS. 5 and 6 are sectional views of a radical-assisted chemical vapor deposition (CVD) apparatus used for forming a spacer oxide film in the method of the present invention; and

FIG. 7 is a graph for illustrating differences of threshold voltages and loading effects, when a spacer oxide film is formed using TEOS and when a spacer oxide film is formed by the method of the present invention.

### DESCRIPTION OF THE EMBODIMENTS

Now, an embodiment of the present invention will be described in detail with reference to the annexed drawings. The embodiment may be modified and should not be used to limit the scope and spirit of the invention. The embodiment has been disclosed for illustrative purposes to those skilled in the art, and the present invention is defined by the accompanying claims. Elements having the same function throughout the descriptions are represented by the same reference numerals, even through they are depicted in different drawings.

In order to form transistors of a semiconductor device in accordance with this embodiment of the present invention, first (as shown in FIG. 1) a plurality of gate stacks 110 are formed on a semiconductor substrate 100.

More particularly, the gate stacks 110 are formed by sequentially laminating a gate insulating film 102 (such as an oxide film), a gate conductive film 104 (such as a polysilicon film), a metal silicide film 106 (such as a tungsten silicide film), and a hard mask film 108 (such as a nitride film) on the semiconductor substrate 100 and by sequentially patterning the hard mask film 108, the metal silicide film 106, the gate conductive film 104, and the gate insulating film 102 by a photo etching process using a photosensitive film (not shown).

After a plurality of the gate stacks 110 are formed, the surfaces of the gate stacks 110 are lightly oxidized so as to alleviate damage to the gate stacks 110 during the etching process. Then, a low-concentration impurity is injected into the semiconductor substrate 100 forming LDD regions (not shown) in the semiconductor substrate 100 at both sides of the gate stacks 110.

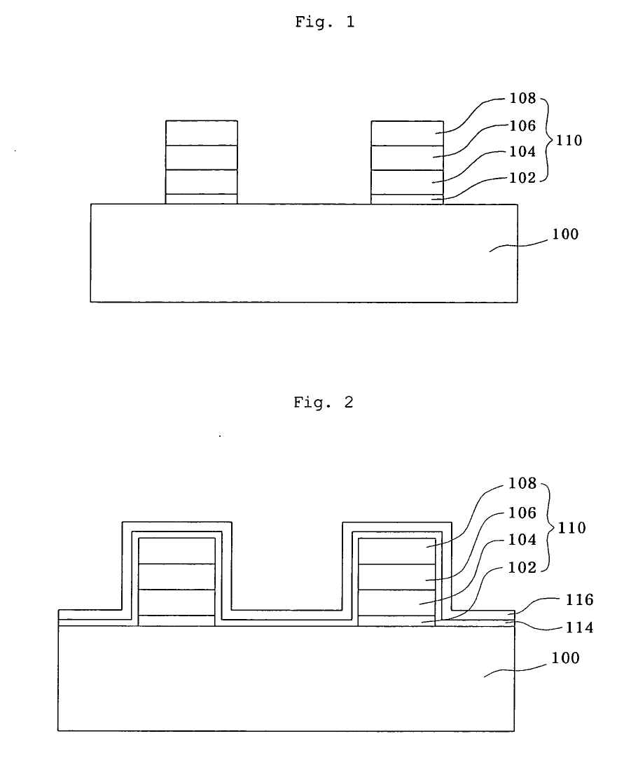

Thereafter, as shown in FIG. 2, a buffer oxide film 114 and a spacer nitride film 116 are sequentially formed on the surface of the semiconductor substrate 100 including the plurality of gate stacks 110. The buffer oxide film 114 serves to prevent the high stress that would result from having the spacer nitride film 116 contact the semiconductor substrate 100. The spacer nitride film 116 serves as a barrier film in an impurity injection step and an etching step, which will be performed subsequently.

The above steps as shown in FIGS. 1 and 2 (i.e., from the step of forming a plurality of the gate stacks 110 to the step of forming the spacer nitride film 114) are the same as those of a conventional method for forming transistors, which is apparent to those skilled in the art, and a detailed description thereof will be omitted.

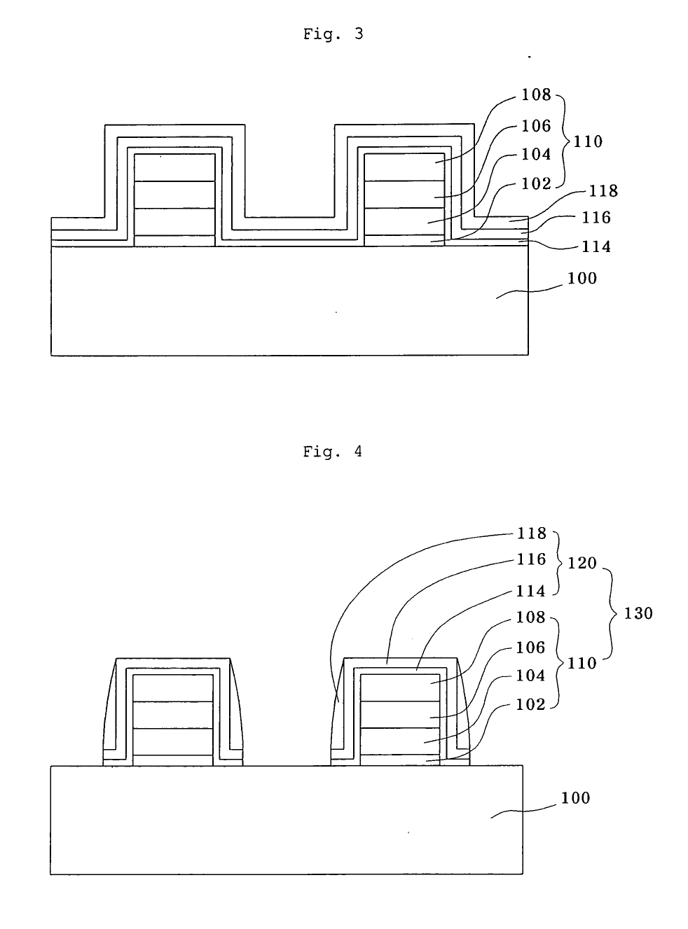

After the spacer nitride film 114 is formed, as shown in FIG. 3, a spacer oxide film 118 is deposited on the surface of the semiconductor substrate 100 including the plurality of gate stacks 110, the buffer oxide film 114 and the spacer nitride film 116.

More particularly, in this embodiment, the spacer oxide film 118 is not formed by CVD (such as LPCVD) or ALD, as is conventionally employed, but is formed using a radical-assisted CVD apparatus.

Hereinafter, the radical-assisted CVD apparatus is described in detail.

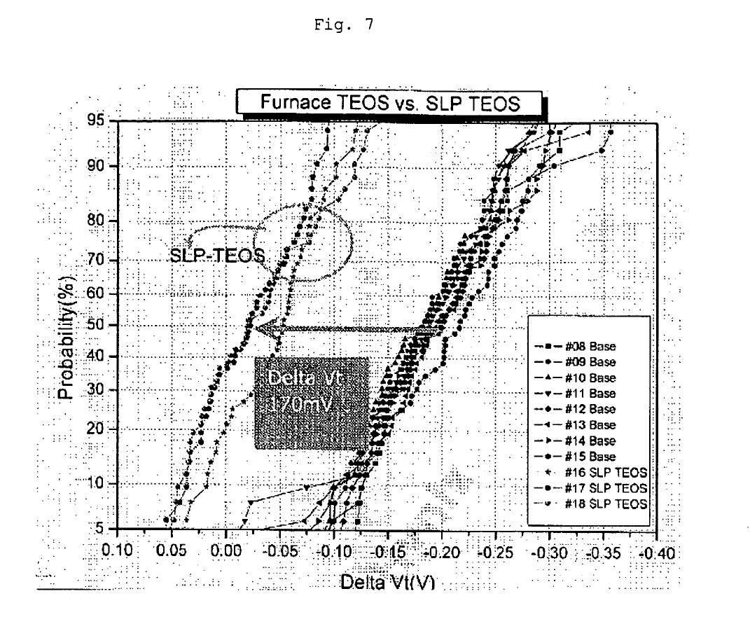

FIGS. 5 and 6 are sectional views of the radical-assisted CVD apparatus used for forming the spacer oxide film 118 in the method of the present invention.

The radical-assisted CVD apparatus, as shown in FIGS. 5 and 6, uses TEOS (Tetra-ethyl-ortho-silicate) as a material gas, and grows a silicon oxide (SiO₂) film as the spacer oxide film 118 on the upper surface of a general semiconductor substrate.

When the spacer oxide film 118 is grown by the radical-assisted CVD apparatus, the inside of a vacuum container 12 of the radical-assisted CVD apparatus is maintained in a vacuum state by an air exhauster 13. The air exhauster 13 is connected to an exhaust port 12b-1 of the vacuum container 12.

A diaphragm 14 made of a conductive material is horizontally installed in the vacuum container 12. The diaphragm 14 has a rectangular shape, and the edge of the diaphragm 14 is pressed by the lower surface of a conductive fixing unit 22, thus forming a hermetically sealed state inside of the vacuum container 12.

Thereby, the inside of the vacuum container 12 is divided into two chambers by the diaphragm 14. The upper chamber forms a plasma generating space 15 and the lower chamber forms a film growing space 16.

The diaphragm 14 has a designated thickness and an overall flat shape similar to that of the horizontal cross section of the vacuum container 12. An internal space 24 is formed in the diaphragm 14.

A semiconductor substrate 11 is disposed on a susceptor 17 installed in the film growing space 16. The surface of the semiconductor substrate 11, on which a film is grown, is parallel with the diaphragm 14.

The electric potential of the susceptor 17 is set to the ground potential, which is equal to the electric potential of the vacuum container 12 set by a ground device 41. Further, a heater 18 is installed in the susceptor 17. The heater 18 maintains a designated temperature of the semiconductor substrate 11.

In order to facilitate the assembly of the vacuum container 12, the vacuum container 12 is comprised of an upper container 12a forming the plasma generating space 15, and a lower container 12b forming the film growing space 16. When the upper container 12a and the lower container 12b are assembled into the vacuum container 12, the diaphragm 14 is installed between the upper container 12a and the lower container 12b.

The diaphragm 14 is installed such that the upper surface of the edge of the conductive fixing unit 22, the lower surface of which presses the edge of the diaphragm 14, contact a lower insulating member 21b out of two insulating members 21a and 21b interposed between the upper container 12a and the diaphragm 14 when a high-frequency electrode 20 is installed, as will be described later.

Thereby, the plasma generating space 15 and the film growing space 16, which are divided from each other, are respectively formed on and under the diaphragm 14. The plasma generating space 15 is defined by the diaphragm 14 and the upper container 12a.

In the radical-assisted CVD apparatus used for forming the spacer oxide film 118 in the method of the present invention, a plasma generating region in the plasma generating space 15 is defined by the diaphragm 4, the upper container 12a, and the planar high-frequency electrode 20 disposed at an approximately middle position therebetween. A plurality of holes 20a are formed through the high-frequency electrode 20. The diaphragm 14 and the high-frequency electrode 20 are fixedly supported by the two insulating members 21a and 21b installed along the inner side surface of the upper container 12a.

An electric power supply rod 29 connected to the high-frequency electrode 20 is installed on the ceiling of the upper container 12a. High-frequency electric power is supplied to the high-frequency electrode 20 by the electric power supply rod 29.

The electric power supply rod 29 is coated with an insulating material 31, thus insulating it from other metal parts.

The diaphragm 14 is connected to the ground device 41 through the conductive fixing unit 22, thus having the same potential as ground. An oxygen gas supply pipe 23a for supplying oxygen gas from the outside to the plasma generating space 15 and a cleaning gas supply pipe 23b for supplying a cleaning gas, such as a fluoride gas, are installed in the insulating member 21a.

The inside of the vacuum container 12 is divided into the plasma generating space 15 and the film growing space 16 by the diaphragm 14. A plurality of through holes 25 are regularly formed throughout the diaphragm 14, in which the internal space 24 is not formed. Each of the through holes 25 has a size (length or diameter) and a structure for preventing the TEOS gas (introduced as the material gas into the film growing space 16) from being reversely diffused into the plasma generating space 15. The plasma generating space 15 and the film growing space 16 are connected to each other only via the through holes 25.

Hereinafter, a method for forming the spacer oxide film 118 using the above radical-assisted CVD apparatus is described.

The semiconductor substrate 11 is transferred to the inside of the vacuum container 12 by a carrier robot (not shown) and is disposed on the susceptor 17. The inside of the vacuum container 12 is decompressed to a designated degree by exhausting air from the inside of the vacuum container 12 to the outside using the air exhauster 13.

Then O₂ gas, including He gas or N₂ gas, is supplied to the plasma generating space 15 of the vacuum container 12 through the oxygen gas supply pipe 23a. A composition ratio of the O₂ gas including He gas or N₂ gas is adjusted by a mass flow controller (MFC).

TEOS gas serving as a material gas is supplied to the internal space 24 of the diaphragm 14 through a material gas supply pipe 28.

The TEOS gas is first supplied to the upper portions of the internal spaces 24 of the diaphragm 14, is equalized by uniformization plates 27b, and is transferred to the lower portions of the internal spaces 24 of the diaphragm 14. Then, the TEOS gas is supplied directly to the film growing space 16 through diffusion holes 26 without contacting plasma. A designated temperature of the susceptor 17 is maintained in advance by the heater 18 installed in the susceptor 17 disposed in the film growing space 16 for fixing the semiconductor substrate 11.

In the embodiment, the O₂ gas (including He gas or N₂ gas) and the TEOS gas are respectively supplied through different inlets. However, the O₂ gas including He gas or N₂ gas may be used as a carrier gas of the TEOS gas.

In the above state, high-frequency electric power is supplied to the high-frequency electrode 20 through the electric power supply rod 29. Electric discharge occurs due to the high-frequency electric power and oxygen plasma 19 is generated around the high-frequency electrode 20 in the plasma generating space 15. Thereby, radicals (active materials), i.e., neutral excited materials, are generated and supplied to the film growing space 16 through the through holes 25. Simultaneously, the TEOS gas serving as the material gas is supplied to the film growing space 16 through the internal spaces 24 and the diffusion holes 26 of the diaphragm 14, as described above.

As a result, the corresponding radicals contact the TEOS gas serving as the material gas in the film growing space 16, and cause a chemical reaction. Then, silicon oxide is deposited on the semiconductor substrate 11 having gate stacks formed thereon, thus forming the spacer oxide film 118.

The pressure of the inside of the film growing space 16 is 1˜300 Torr so that the deposited spacer oxide film 188 has an overall uniform thickness.

The oxygen gas serves to accelerate decomposition of the TEOS gas and to volatilize by-products generated during the formation of the spacer oxide film 118. The flow rate of the oxygen gas is 5˜2,000 sccm.

A flow rate of the TEOS gas varies according to experimental conditions. When the above condition is applied, the flow rate of the TEOS is 120˜3,000 sccm.

In order to form the spacer oxide film 118 having a uniform thickness throughout all gate stacks of the semiconductor substrate 11, a rotary shaft is connected to the susceptor 17 so that the susceptor 17 can be rotated at a designated speed. The rotational speed of the susceptor 17 is 1˜10 times per sec (i.e., 60˜600 rpm).

Although the oxygen gas uses O₂ gas, the oxygen gas may use O₃ gas. Further, although the nitrogen gas uses N₂ gas, the nitrogen gas may use NO, N₂O, or NO₂ gas.

The susceptor 17 installed in the film growing space 16 is not a batch-type susceptor, which simultaneously loads several substrates, but is a single-type susceptor, which loads one substrate so that the spacer oxide film 118 having a uniform thickness is formed on the substrate using the above deposition condition.

LPCVD may cause thermal impact to a substrate and PECVD may cause plasma to directly attack a substrate, thus causing a defect of the substrate. Accordingly, the radical-assisted CVD apparatus, which performs deposition at a low temperature and prevents plasma from directly attacking a substrate, is used for depositing the spacer oxide film 118 of the present invention.

As described above, the spacer oxide film 118 is not deposited on a plurality of semiconductor substrates, but is deposited on a single semiconductor substrate using the radical-assisted CVD apparatus. Here, it is possible to deposit the spacer oxide film 18 having a uniform thickness throughout all gate stacks of one semiconductor substrate by adjusting the flow rate of the TEOS gas serving as the material gas, the pressure in the film growing space 16, the kind and flow rate of the carrier gas, and the temperature of the heater 18 and rotational speed of the susceptor 17.

Hereinafter, the method for forming transistors of a semiconductor device is described again in detail.

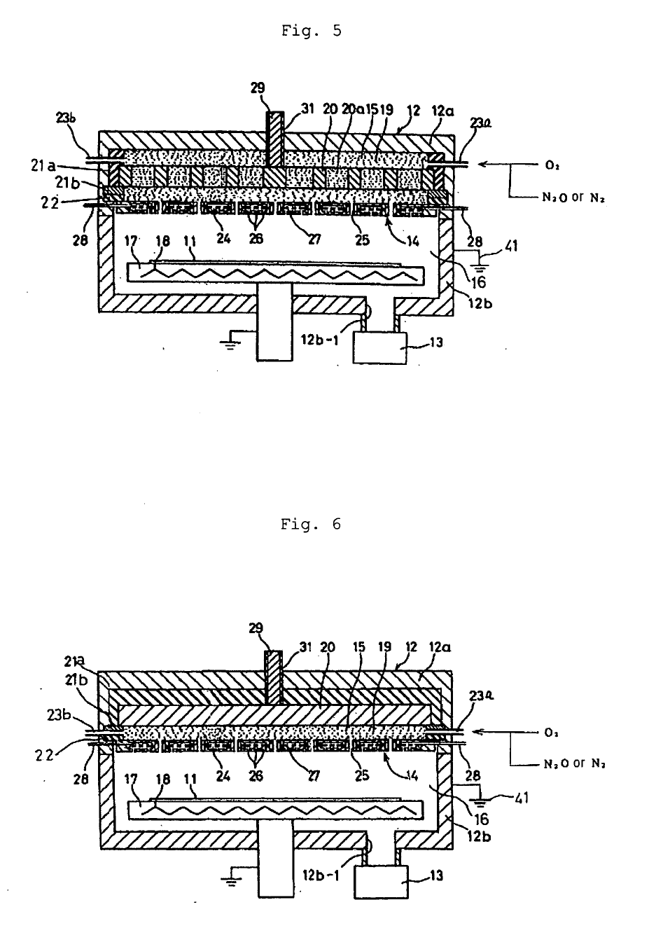

With reference to FIG. 4, after the formation of the spacer oxide film 118, the buffer oxide film 114 and the spacer nitride film 116 are sequentially etched and the spacer oxide film 118 is blanket-etched according to a conventional transistor forming process, thereby, forming gate spacers 120 on both side walls of the plurality of gate stacks 110. Accordingly, a plurality of gates 130 comprised of the gate stacks 110 and the gate spacers 120 are formed on the semiconductor substrate 100. Thereafter, a high-concentration impurity is injected into the semiconductor substrate 100 at both sides of the plurality of gates 103, thereby forming sources/drains (not shown). Thereby, transistors having an LDD structure are obtained.

In the above method for forming the transistors of the semiconductor device in accordance with the embodiment, the spacer oxide film 118 having a uniform thickness is formed throughout all regions of the semiconductor substrate 100 regardless of the density of the gate stacks 110. Accordingly, the gate spacers 120 obtained by blanket-etching the spacer oxide film 118 and the gates 130 including the gate spacers 120 have a uniform thickness, thereby improving the electrical characteristics of the transistors of the semiconductor device, for example the Vt characteristics of the PMOSs.

Hereinafter, improvements of loading effect and difference (ΔVt) of threshold voltages when a spacer oxide film of a semiconductor device is formed using the radial-assisted CVD apparatus in accordance with the embodiment of the present invention, will be described through experimental examples. Other contents, which are not described herein, are apparent to those skilled in the art, and a detailed description thereof will be thus omitted.

FIG. 7 is a graph for illustrating differences of threshold voltages and loading effects, when a spacer oxide film is formed using TEOS and when a spacer oxide film is formed by the method of the present invention.

As shown in FIG. 7, when a spacer oxide film is formed by conventional CVD (such as LPCVD), gate spacers and gates have a nonuniform thickness according to regions of a semiconductor substrate whereon these structures are formed. The resulting variance in threshold voltages among PMOS transistors in different regions of the substrate reaches −203 mV.

On the other hand, when a spacer oxide film is formed by the method of the present invention using the radical-assisted CVD apparatus, gate spacers and gates have substantially the same thickness throughout different regions of a semiconductor substrate. The variance in threshold voltages among PMOS transistors in different regions of the substrate is −156 mV. That is, the spacer oxide film formed by the method of the present invention using the radical-assisted CVD apparatus reduces the variance in threshold voltages by approximately 47 mV, compared to the spacer oxide film formed by conventional CVD. In other implementations, the threshold voltage variance may be no more than −165 mV or −160 mV.

Further, when the spacer oxide film is formed by conventional CVD, a difference of loading effects among the regions of the PMOS reaches −192 mV, and when the spacer oxide film is formed by the method of the present invention using the radical-assisted CVD apparatus, a difference of loading effects among the regions of the PMOS reaches −22 mV. That is, the spacer oxide film formed by the method of the present invention using the radical-assisted CVD apparatus improves a difference of loading effects by approximately 170 mV, compared to the spacer oxide film formed by conventional CVD.

As apparent from the above description, the present invention provides a method for forming transistors of a semiconductor substrate, in which gate spacers and gates have a uniform thickness throughout all regions of a semiconductor substrate regardless of the density of a plurality of gate stacks.

Accordingly, electrical characteristics of the transistors of the semiconductor device are improved, and the semiconductor device can be stably operated, thereby improving quality and reliability, and improving the yield of the semiconductor device.

Although the embodiment of the present invention has been disclosed for illustrative purposes, those skilled in the art will appreciate that various modifications, additions and substitutions are possible, without departing from the scope and spirit of the invention as disclosed in the accompanying claims.

What is claimed is:

1. A method for forming a semiconductor device having a plurality of transistors, the device comprising:
forming a first gate stack on a first region of a substrate, the first region having a high density of gate stacks, the first gate stack being associated with a first transistor;
forming a second gate stack on a second region of a substrate, the second region having a low density of gate stacks, the second gate stack being associated with a second transistor; and
forming first and second gate oxide spacers at least on sidewalls of the first and second gate stacks, respectively, wherein the gate oxide spacer forming step includes:
flowing a first gas into a plasma generating chamber of a deposition apparatus to generate a plasma and a plurality of radicals using the first gas;
flowing the radicals into a film growing chamber that is separated from the plasma generating chamber, so that the radicals may react with a second gas provided in the film growing chamber to form a spacer oxide film on the first and second gate stacks; and
etching the spacer oxide film to define the first and second gate oxide spacers for the first and second gate stacks, respectively.

2. The method as set forth in claim 1, further comprising:
oxidizing surfaces of the first and second gate stacks;
forming LDD regions in the substrate at both sides of the plurality of gate stacks; and
sequentially forming a buffer oxide film and a spacer nitride film on the plurality of gate stacks.

3. The method as set forth in claim 2, wherein the second gas includes TEOS (Tetra-ethyl-ortho-silicate) as a silicon source.

4. The method as set forth in claim 3, wherein the TEOS is first supplied to the plasma generating chamber and then to the film growing chamber, wherein the TEOS is provided within the plasma generating chamber using a carrier gas, the carrier gas including He or N₂ or both.

5. The method as set forth in claim 1, wherein the pressure of the film growing chamber is set to 1˜300 Torr.

6. The method as set forth in claim 1, wherein the first gas includes O₂, the first gas is flowed into the plasma generating chamber at a flow rate of 5˜2,000 sccm to accelerate decomposition of the TEOS and volatilize by-products generated during the formation of the spacer oxide film.

7. The method as set forth in claim 3, wherein the TEOS is flowed into the deposition apparatus at a flow rate of 120˜3,000 sccm.

8. The method as set forth in claim 1, wherein the temperature of a heater of the deposition apparatus is set to 400˜600° C. to increase the deposition density and the deposition rate of the spacer oxide film.

9. The method as set forth in claim 1, wherein the spacer oxide film is formed under the condition that a susceptor of the deposition apparatus for supporting the semiconductor substrate is rotated to form the spacer oxide film having substantially the same thickness.

10. The method as set forth in claim 9, wherein the rotational speed of the susceptor is 60˜600 rpm.

11. The method of claim 1, wherein the difference between a first threshold voltage of the first transistor and a second threshold voltage of the second transistor is no more than 165 mV.

12. The method of claim 11, wherein the 165 mV is the maximum threshold voltage variance for the transistors formed on the substrate.

13. The method of claim 12, wherein the substrate is a wafer.

14. A method for forming a semiconductor device having a plurality of transistors with substantially the same gate oxide spacer thickness, the device comprising:
forming a first gate stack on a first region of a substrate, the first region having a high density of gate stacks, the first gate stack being associated with a first transistor;
forming a second gate stack on a second region of a substrate, the second region having a low density of gate stacks, the second gate stack being associated with a second transistor; and
forming first and second gate oxide spacers at least on sidewalls of the first and second gate stacks, respectively, wherein the gate oxide spacer forming step includes:
flowing a first gas into a plasma generating chamber of a deposition apparatus to generate a plasma and a plurality of radicals using the first gas;
flowing the radicals into a film growing chamber that is separated from the plasma generating chamber, so that the radicals may react with a second gas provided in the film growing chamber to form a spacer oxide film on the first and second gate stacks; and
etching the spacer oxide film to define the first and second gate oxide spacers for the first and second gate stacks, respectively,
wherein the reaction of the radicals of the first gas with the second gas provides the spacer film with substantially the same thickness in the first and second regions, so that the first and second transistors associated with the first and second gate spacers have a reduced threshold voltage variance.

15. The method of claim 14, wherein the first gas includes oxygen and the second gas includes silicon.
